(19) United States
(12) Patent Application Publication
(10) Pub. No.: US 2008/0253095 A1
(43) Pub. Date: Oct. 16, 2008

(54) Electronic Circuit Assembly, Device Comprising Such Assembly and Method for Fabricating Such Device

(76) Inventors: Xavier Baraton, Montrouge (FR); Carlo Cognetti, Milan (IT); Risto Tuominen, Espoo (FI)

Correspondence Address: GARDERE WYNNE SEWELL LLP;INTELLECTUAL PROPERTY SECTION, 3000 THANKSGIVING TOWER, 1601 ELM ST, DALLAS, TX, 75201-4761, US

(21) Appl. No.: 11/632,571

(22) PCT Filed: Jul. 12, 2005
(86) PCT No.: PCT/EP2005/008741

§ 371 Date: Dec. 10, 2007

(30) Foreign Application Priority Data
Jul. 16, 2004 (EP) 04291824.3

(51) Int. Cl. H05K 5/00

(52) U.S. Cl. 361/752

(57) ABSTRACT

An electronic circuit assembly (A1) comprises a casing (1) having two opposite outer faces (S1ₛᵤₚ, S1_{inf}) and an inner space (V1) separate from each outer faces by a respective closing portion (4, 5), and a single die (10) incorporating an integrated circuit. The casing (1) includes integrated electrically conducting elements (21) connecting terminals of the die (11) to pads of the casing (31ₛᵤₚ). The electrically conducting elements also connect sets of pads respectively located on each one of the opposite outer face of the casing (31ₛᵤₚ, 31_{inf}). Such electronic circuit assemblies (A1-A4) are suitable for being stacked with bonding means (300, 303) arranged between respective sets of pads (31ₛᵤₚ, 32ᵢₙₜ) of two successive electronic circuit assemblies in a stack.

The invention relates to an electronic circuit assembly and to a device comprising such assembly. It further relates to a method for fabricating such device.

The general trend for reducing the size of electronic devices leads to stack several dice one upon another within a device. The base surface of such device is thus limited in size while more complex functions can be achieved by the device.

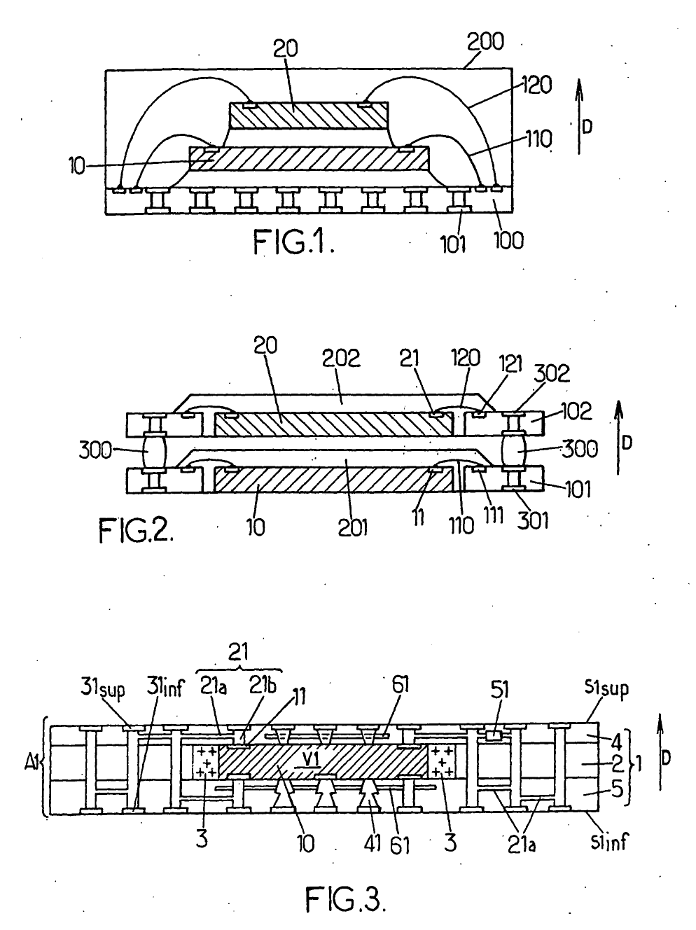

Several technologies have been developed for electrically connecting dice that are stacked within a single device. FIGS. 1 and 2 illustrate two existing technologies.

According to FIG. 1, at least two dice 10, 20 are stacked within a single circuit package. The dice 10, 20 are arranged so that respective main faces of the dice are perpendicular to the stacking direction D. The die 20 is fixed onto the die 10 with appropriate gluing means. The circuit package comprises a base element 100 for supporting the die stack and a cap 200 for enclosing the dice. Each die 10, 20 is electrically connected to pads-arranged in the base element 100, around a portion of the base element 100 located beneath the stack. Wirebonding 110, 120 is used for these connections, and a resin of the cap 200 is cast over the stack and the wires for protection and mechanical strengthening purposes.

A drawback of such die stacking technology results from the assembly steps that are necessary. Indeed, it involves numerous and complex steps comprising die fixing, wirebonding and moulding. Furthermore, when successive dice in the stack have substantially same sizes, an interposer must be arranged therebetween, so that connecting wires can be arranged on the upper face of the lower die. The total height of the stack is thus increased, which limits the capacity of the device to be integrated.

Another drawback of such die stacking technology results from the device operating tests which can be carried out only after the whole assembly is completed. It is so because the electrical terminals 101 in the base element 100 are necessary for connecting the circuits to a testing head. Then a yield loss has an important cost impact, because of the number of dice in the stack and because of the number of assembling steps per stack.

Alternatively, the so-called “flip-chip” process may be used for stacking dice one upon another. According to said flip-chip process, which is well known per se, solder bumps are arranged between matching terminals located on respective outer faces of two dice. But the flip-chip process must be combined with wirebonding for a same stack, because it is limited for connecting die terminals that are facing one another.

FIG. 2 illustrates another technology called “substrate stacking”. In this case, each die 10, 20 is fixed onto a respective substrate 101, 102. The substrates 101, 102 are fixed one upon another with solder balls 300 arranged between respective pads 301, 302 located in peripheral portions of each substrate. Each die 10, 20 may be laid on an upper surface of the corresponding substrate 101, 102 or inserted into an opening of the substrate. Electrical connections 110, 120 using wirebonding process extend between terminals of each die 10, 20 and electrically conducting elements 111, 121 arranged in the corresponding substrate 101, 102. For protection purpose, each assembly of a die together with the corresponding substrate further comprises a resin cap 201, 202 moulded over the die and a part of the substrate.

Alternatively, each die can be fixed on and electrically connected to the corresponding substrate using the flip-chip process. Then, the substrate extends beneath the die and solder bumps arranged at points of an array connect terminals of the die to pads of the substrate. A resin portion may fill in the gap between the die and the substrate around each bump.

According to the substrate stacking technology, the solder balls 300 have two functions. First, they hold together the successive substrates 101, 102 of the stack. Besides, they form electrical connections between the substrates 101, 102. As the solder balls 300 can only be arranged on each substrate in a peripheral portion surrounding the die, the number of inter-substrate connections thus obtained may be insufficient in respect of the electrical design of the whole device.

Furthermore, in both the die stacking and the substrate stacking technologies described hereabove, the number of electrical connections connecting each die is limited when wirebonding is used. Indeed, in the case of die stacking, electrical connections between a die and the base element of the package can only be arranged near the peripheral edge of the die. The same limitation applies for substrate stacking combined with wirebonding.

Documents DE 102 07 308 and EP 0 802 566 disclose electronic circuit assemblies in the form of casing stacks, in which each casing encloses two dice. Then the thickness of each casing is quite important. Furthermore, the dice are arranged back to back within each casing, so that the assembly does not suit well for applications connecting identical dice enclosed in respective casings. Indeed, successive dice in two neighbouring casings along the stacking direction are facing one another and, for identical dice, their respective corresponding die terminals are not in line with one another.

It is therefore an object of the present invention to provide an electronic circuit design allowing stacking with a greater number of electrical connections.

The invention thus proposes an electronic circuit assembly comprising
a casing having two opposite outer faces and an inner space separate from each of said outer faces by a respective closing portion,
first and second sets of pads each located on a respective one of said outer faces of the casing, and
a die incorporating an integrated circuit and electrical terminals, said die being affixed to the casing within said inner space.

The casing includes integrated electrically conducting elements connecting terminals of the die to pads of the casing, and connecting pads of said first set of pads to pads of said second set of pads. Furthermore, each one of said first and second sets of pads is arranged for making it possible to connect said electronic circuit assembly to respective other electronic circuit assemblies with a pad mirror-matching relationship.

An electronic circuit assembly according to the invention comprises only one single die arranged within the casing.

Such electronic circuit assembly is suitable for being stacked with other electronic circuit assemblies thanks to the pads located on the outer faces of the casing and the electrically conducting elements connecting these pads. Indeed, electrical connections can thus be achieved between several electronic circuit assemblies stacked one on another.

Because only one die is arranged within each casing, the casing thickness is limited. Then the total length of a stack is reduced, which makes it possible to incorporate the stack within a small-sized device.

Thanks to the closing portions of the casing provided on both sides of the die, it is possible, in an assembly according to the invention, to connect terminals of the die located in a middle part of the die, and not only located near an edge of the die. Therefore, the die can be provided with a great number of electrical connections, by arranging as many terminals as necessary on at least one whole face of the die.

Several electronic circuit assemblies according to the invention can be stacked one on another, in a manner similar to the substrate stacking technology previously described. But connections between two successive assemblies in the stack can be arranged with pads located on, the whole surface of each casing face, so that a great number of inter-casing connections can be achieved. In particular, at least one pad can be supported by one of said closing portions of the casing.

Advantageously, pads of at least one of said first and second sets of pads can be arranged in array, on the corresponding outer face of the casing. Then the mirror-matching relationship between the sets of pads of two successively stacked electronic circuit assemblies can easily be achieved.

Consequently, the invention is an improvement of the substrate stacking technology for at least two reasons. First, the number of die connections can be increased, as well as the number of inter-casing connections. Second, no wirebonding is necessary for connecting dies, so that the circuit assembly obtained is particularly strong.

Another advantage of a device according to the invention results from the providing of pads on the casing. Indeed, thanks to these pads, the electronic circuit assembly can be connected to a testing head before it is further connected to other electronic circuit assemblies or whatever external electrical circuit. Then, in case of malfunctioning of the die or in case of any defect in the assembly, the electronic circuit assembly can be discarded without impairing any other assembly or external circuit. The cost impact due to such malfunctioning or defect is then limited.

Because each casing contains only one die, a high manufacturing yield can be increased compared to prior art solutions, even if failures or defects may occur in some dice. Indeed, when the test of an assembly reveals a malfunctioning, discarding the assembly induces only one die loss, instead of several dice which are lost for multi-die casings.

According to a preferred embodiment of the invention, the opposite outer faces of the assembly casing are substantially parallel one to the other. Then, two other electronic circuit assemblies respectively connected on each side of the casing are in a parallel orientation relationship, so that the assembly stack has a general outer shape which is simple and compatible with many packaging designs.

Advantageously, the pads of the casing are designed for ball soldering. Then a currently available ball soldering process can be used for connecting two electronic circuit assemblies one to the other.

Still another advantage of the invention results from the arrangement of one single die within each casing. Identical dice placed in respective casings can be stacked so that they face a common direction. Then, same terminals of different dice are superposed. So, conducting elements of the casings can be easily designed, for connecting together the corresponding pads of the stacked dice. This is particularly useful for applications implementing memory dice, which can be stacked so as to form a memory module with higher capacity.

In one embodiment of the invention, the die may have two sets of electrical terminals on respective faces, which are preferably opposite.

In another embodiment of the invention, each one of the two closing portions of the casing has electrical terminals arranged on respective inner faces of the closing portions. When the die has terminals of its both faces, then it can be connected to the casing on its both sides, with an increased number of electrical terminals.

The invention also proposes a device comprising at least one such electronic circuit assembly. In particular, the device may comprise several electronic circuit assemblies stacked along a stacking direction substantially perpendicular to the respective casing opposite outer faces of said assemblies. Two successive assemblies along said stacking direction are connected one to the other via bonding means connecting respective sets of pads of said successive assemblies.

Advantageously, the connected respective pads of two successive assemblies in the stack are facing one another. Then, the respective pad sets of the two electronic circuit assemblies are in a mirror relationship, so that a face to face connecting process can be used.

Finally, the invention proposes a method for fabricating a device comprising the following steps:
a—obtaining a first electronic circuit assembly of the type previously described;
b—obtaining a second electronic circuit assembly having a respective set of pads arranged on an outer face of said second assembly in mirror-matching relationship with a first one of the sets of pads of said first assembly;
c—obtaining a third electronic circuit assembly having a respective set of pads arranged on an outer face of said third assembly in mirror-matching relationship with a second one of the sets of pads of said first assembly;
d—connecting said second electronic circuit assembly to said first electronic circuit assembly by arranging a first set of bounding means between pads of said second assembly and pads of said first-set of pads of said first assembly; and
e—connecting said third electronic circuit assembly to said first electronic circuit assembly by arranging a second set of bounding means between pads of said third assembly and pads of said second set of pads of said first assembly.

Said second electronic circuit-assembly may comprise a base element of the device. Then the device can be easily incorporated into an apparatus without any useless gap between the device and the apparatus. Therefore, the apparatus may be small-sized, which is especially required for apparatuses such as mobile communication terminals, as for an example.

Said third electronic circuit assembly may be provided with another set of pads opposite to said outer face of said third assembly and arranged for connecting said third assembly to a fourth electronic circuit assembly having a respective set of pads in mirror-matching relationship with said another set of pads of said third assembly.

These and other aspects of the invention will become apparent from the non-limiting embodiments described hereafter in reference to the following drawings:

FIG. 1 is a sectional view of a die stack according to a first technology known from prior art;

FIG. 2 is a sectional view of a stack of die substrates according to a second technology known from prior art;

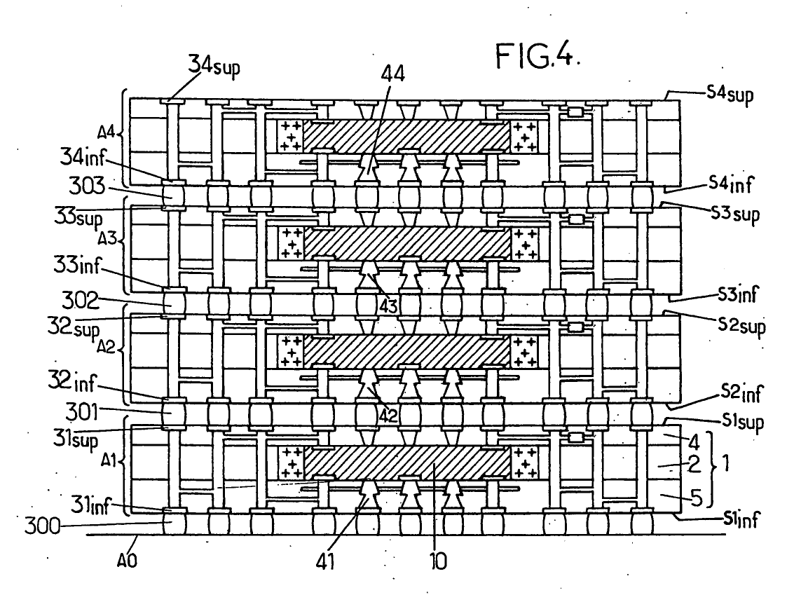

FIG. 3 is a sectional view of an assembly according to the invention; and

FIG. 4 is a sectional view of an assembly stack according to the invention.

Through the figures, same reference numbers refer to similar elements, or to elements having similar functions. Furthermore, for sake of clarity, the sizes of the elements represented do not correspond to actual sizes of said elements.

All these figures represent at least one die which has main faces oriented horizontally and perpendicular to the plane of the figures. Letter D denotes a direction oriented upwards, and words like “on”, “under”, “upper” and “lower” used hereinafter are used in consideration of the direction D.

FIGS. 1 and 2 have already been described previously.

Referring to FIG. 3, a casing element 2 has two opposite outer faces, namely an upper face and a lower face. Said faces are parallel one to the other, and oriented perpendicular to the direction D. The casing element 2 is provided with an empty space V1 in a central part of it. The space V1 is open upwards and downwards. The overall dimensions of the casing element 2 in a plane perpendicular to the direction D may be 8 millimeters×8 millimeters, and the inner dimensions of the space V1 in the same plane may be 4 millimeters×4 millimeters. A die 10 is affixed to the casing element 2, within the space V1, with a glue or resin portion 3 arranged between the die 10 and the casing element 2. Therefore, the casing element 2 surrounds the die 10 in a plane perpendicular to the direction D.

One possible method for assembling the die 10 into the casing element 2 is to provide initially the casing element 2 with a bottom plate (not represented) closing the space V1 downwards. The bottom plate is perpendicular to the direction D and may be about 40 micrometers thick. Then the die 10 is introduced into the space V1 from the upper side of the casing element 2, until it is supported by the bottom plate. The lateral gap between the die 10 and the casing element 2 is filled with glue or resin, and then the bottom plate is eliminated, for example by polishing.

The die 10 is of common type with an electronical circuit integrated. It is provided with electrical terminals 11 on at least one face, for example the upper face of the die 10. In one type of application, the die may have two sets of electrical terminals on its both sides. The die 10 may be 3 millimeters×3 millimeters in a plane perpendicular to the direction D, and 80 micrometers thick along the direction D.

Optionally, the upper and lower faces of the joined casing element 2 and die 10 may be polished so that continuous and planar surfaces extend over the casing element 2 and the die 10 on the upper and lower sides.

Then, in a known manner, a layer 4 is applied on the upper face of the joined casing element 2 and die 10. The layer 4 incorporates pads 31ₛᵤₚ arranged on its upper face S1ₛᵤₚ, and electrically conducting elements 21 that connect terminals 11 of the die 10 to some of the pads 31ₛᵤₚ. Layer 4 may consist in several sub-layers (not represented) stacked one on another along the direction D, so that it is laminated. The sub-layers are alternatively made of electrically insulating or conducting materials, such as a synthetic material or copper. These sub-layers may be applied as continuous films and then etched for obtaining the conducting elements in the form of tracks 21a and vias 21b, respectively substantially parallel to and perpendicular to the outer face S1ₛᵤₚ.

A layer 5 similar to layer 4 is applied on the lower face of the joined casing element 2 and die 10. Similarly, layer 5 incorporates pads 31_{inf} arranged on its lower face S1 ins and additional electrically conducting elements. As for an example of variations that can be introduced in the device, layer 4 is represented at FIG. 3 with a single level of tracks 21a, whereas layer 5 is represented with two different levels of tracks.

Electrical connections are also arranged through the casing element 2 for connecting some of the pads 31ₛᵤₚ to some of the pads 31_{inf}.

The casing element 2, together with layers 4 and 5, constitute the casing 1. Layers 4 and 5 constitute closing portions of the casing 1 located between the space V1 and the outer surfaces of the casing, S1ₛᵤₚ or S1_{inf} respectively. The height of the whole casing 1 may be less than 250 micrometers, along direction D. The die 10 is therefore embedded in the casing 1 and electrically connected to pads arranged on either side of the casing 1 via the elements 21. The casing 1 and the die 10 constitute the electronic circuit assembly A1. It is specified that the invention is not limited to the fabrication method of the assembly A1 just described, but that it may be combined with any fabrication method suitable for obtaining a similar assembly.

The pads 31ₛᵤₚ and 31_{inf} may be arranged at points of a BGA (standing for “ball grid array”) on each outer face S1ₛᵤₚ, S1_{inf} of the casing 1. Then, the layout of the pads is simple and compatible with design rules that are common in the art. Some of the pads 31ₛᵤₚ, 31_{inf} may be located on one of the closing portions of the casing 1. In particular, a respective pad array may extend continuously on each of the face S1ₛᵤₚ, S1_{inf}. Then a great number of pads can be arranged on the casing 1, suitable with complex circuits which require numerous electrical connections.

Optionally, the assembly A1 further comprises at least one thermally conducting element 41 extending from a portion of the casing 1 close to the die 10 to at least one pad 31ₛᵤₚ, 31_{inf}. Such thermally conducting element 41 is useful for dissipating heat produced in the die 10 under operation. The pad used for the thermally conducting element 41 may be arranged on one of the outer faces S1 up, Slinf in a similar way than the pads used for the electrically conducting elements 21. Furthermore, the pads for thermally conducting elements 41 and the pads for electrically conducting elements 21 can be located on each outer face S1ₛᵤₚ, S1_{inf} of the casing 1 at different respective points of a same BGA. For better heat dissipation, the thermally conducting element 41 may extend substantially perpendicular to the outer face of the casing 1 corresponding to the pad it connects. Advantageously, it is provided within the layers 4 and/or 5 in the form of a via. This via may be electrically insulated from the die 10.

In one embodiment, the assembly A1 further comprises at least one electronic component 51 integrated in the casing 1. Such component 51 may be a resistor, a capacitor, a coil, or any other passive or active component. Thus a high integration level can be achieved, combining, within the casing 1, electrical components integrated within the die 10 and other components arranged outside this die. According to a preferred embodiment, the component 51 may be integrated within the layer 4 and/or 5.

In one embodiment, the assembly A1 further comprises at least one radiation shield 61 arranged in the layers 4 or 5 for stopping electromagnetic radiations produced in the die 10 under operation. Such shield may be a portion of a metal sub-layer, for example of copper, oriented parallel to the outer faces S1ₛᵤₚ, S1_{inf}. It is useful when the radiations produced by the circuit incorporated in the die 10 may disturb any other circuit external to the die 10, for example a circuit incorporated in another assembly connected to the assembly A1.

According to FIG. 4, several electronic circuit assemblies similar to the assembly just described (referenced A1-A4 for example) are connected on their respective opposite outer faces (Snₛᵤₚ, Sn_{inf} for assembly An, n being an integer from 1 to 4) to form a stack. Advantageously, the respective opposite outer faces of the casing of each electronic circuit assembly are substantially parallel one to the other. Then, the stack extends parallel to the direction D, so that the stack is compact and can be produced with production equipments that are less complex.

The mutually connected pads of two successive assemblies in the stack are facing one another. Furthermore, the pads of each casing (referenced 3nₛᵤₚ and 3n_{inf} for assembly An) may be designed for ball soldering. Then, the bonding means 301-303 arranged between the pads of successive assemblies in the stack may comprise solder balls. Production ball-soldering equipments that are commercially available can thus be used. The pads for the thermally conducting elements in each assembly (referenced 4n for the assembly An) may be connected one to the other in a manner similar to the pads for the electrically conducting elements. Hence, continuous paths for dissipating heat are arranged through the whole stack along the direction D, so that the maximum temperature reached in the device under operation is limited.

Furthermore, the assembly A1 may be connected on its lower outer face S1_{inf} to a base element A0. In respect to the connection of the assembly A1, the base element A0 can be considered in a similar manner as the assembly A2.

It shall be understood that many changes may be introduced in the method for fabricating stacked device that has been just described. In particular, the layout of the electrically or thermally conducting elements within the casing, as well as the corresponding pads, may be varied. Furthermore, these conducting elements and pads may be produced using basic process steps different from those cited.

1. Electronic circuit assembly (A1) comprising:
a casing (1) having two opposite outer faces (S1ₛᵤₚ, S1_{inf}) and an inner space (V1) separate from each of said outer faces by a respective closing portion (4, 5),
first and second sets of pads (31ₛᵤₚ, 31_{inf}) each located on a respective one of said outer faces of the casing (1), and
a die (10) incorporating an integrated circuit and electrical terminals (11), said die (10) being affixed to the casing (1) within said inner space (V1),
wherein the casing (1) includes integrated electrically conducting elements (21) connecting terminals of the die (11) to pads of the casing (31ₛᵤₚ), and connecting pads of said first set of pads (31ₛᵤₚ) to pads of said second set of pads (31_{inf}),
and wherein each one of said first and second sets of pads (31ₛᵤₚ, 31_{inf}) is arranged for making it possible to connect said electronic circuit assembly (A1) to respective other electronic circuit assemblies with a pad mirror-matching relationship,
the assembly being characterized in that only one single die is arranged within the casing.

2. Electronic circuit assembly according to claim 1, wherein at least one pad (31ₛᵤₚ, 31_{inf}) is supported by one of said closing portions of the casing (4, 5).

3. Electronic circuit assembly according to claims 1 or 2, wherein the pads of at least one of said first and second sets of pads (31ₛᵤₚ, 31_{inf}) are arranged in array.

4. Electronic circuit assembly according to any one of the preceding claims, wherein said opposite outer faces of the casing (S1ₛᵤₚ, S1_{inf}) are substantially parallel one to the other.

5. Electronic circuit assembly according to any one of the preceding claims, wherein the pads (31ₛᵤₚ, 31_{inf}) are designed for ball soldering.

6. Electronic circuit assembly according to any one of the preceding claims, further comprising at least one thermally conducting element (41) extending from a portion of the casing (1) close to the die (10) to at least one pad (31ₛᵤₚ, 31_{inf}).

7. Electronic circuit assembly according to claim 6, wherein said thermally conducting element (41) extends substantially perpendicular to the outer face of the casing corresponding to said at least one pad (31ₛᵤₚ, 31_{inf}).

8. Electronic circuit assembly according to any one of the preceding claims, further comprising at least one electronic component (51) integrated in the casing (1).

9. Electronic circuit assembly according to any one of the preceding claims, wherein said die (10) is a memory die.

10. Electronic circuit assembly according to any one of the preceding claims, wherein the die (10) has two sets of electrical terminals on respective faces of said die.

11. Electronic circuit assembly according to any one of the preceding claims, wherein each one of the two closing portions of the casing (4, 5) has electrical terminals arranged on respective inner faces of said closing portions.

12. Device comprising at least one electronic circuit assembly (A1-A4) according to any one of the preceding claims.

13. Device according to claim 12, comprising several electronic circuit assemblies (A1-A4) stacked along a stacking direction (D) substantially perpendicular to the respective casing opposite outer faces of said assemblies (S1ₛᵤₚ-S4ₛᵤₚ, S1_{inf}-S4_{inf}), wherein two successive assemblies along said stacking direction are connected one to the other via bonding means (300-303) connecting respective sets of pads of said successive assemblies (31ₛᵤₚ-34ₛᵤₚ, 31_{inf}-34_{inf}).

14. Device according to claim 13, wherein the connected respective pads of two successive assemblies in the stack (31ₛᵤₚ, 32_{inf}) are facing one another.

15. Device according to claim 14, wherein the bonding means (300-303) comprise solder balls.

16. Method for fabricating an electronic device comprising the following steps:
a—obtaining a first electronic circuit assembly (A1) according to any one of the claims 1 to 11;
b—obtaining a second electronic circuit assembly (A0) having a respective set of pads arranged on an outer face of said second assembly in mirror-matching relationship with a first one of the sets of pads of said first assembly (31_{inf})
c—obtaining a third electronic circuit assembly (A2) having b respective set of pads (32_{inf}) arranged on an outer face of said third assembly (S2_{inf}) in mirror-matching relationship with a second one of the sets of pads of said first assembly (31ₛᵤₚ);
d—connecting said second electronic circuit assembly (A0) to said first electronic circuit assembly (A1) by arranging a first set of bounding means (300) between pads of said second assembly and pads of said first set of pads of said first assembly (31_{inf}); and
e—connecting said third electronic circuit assembly (A2) to said first electronic circuit assembly (A1) by arranging a second set of bounding means (301) between pads of said third assembly and pads of said second set of pads of said first assembly (31ₛᵤₚ).

17. Method according to claim 16, wherein the bonding means (300, 301) comprise solder balls.

18. Method according to claim 16 or 17, wherein said second electronic circuit assembly (A0) comprises a base element of the device.

19. Method according to any one of claims 16 to 18, wherein said third electronic circuit assembly (A2) is provided with another set of pads (32ₛᵤₚ) opposite to said outer face of said third assembly (S2_{inf}) and arranged for connecting said third assembly (A2) to a fourth electronic circuit assembly (A3) having a respective set of pads (33_{inf}) in mirror-matching relationship with said another set of pads of said third assembly (32ₛᵤₚ).
